(19) United States
(12) Patent Application Publication
(10) Pub. No.: US 2019/0393385 A1
(43) Pub. Date: Dec. 26, 2019

(54) MANUFACTURING METHOD OF COLOR CONVERSION DIODE

(71) Applicant: Lightizer Korea Co., Ltd., Yongin-si (KR)

(72) Inventors: Jae Sik MIN, Seongnam-si (KR); Jae Yeop LEE, Seongnam-si (KR); Byoung Gu CHO, Seongnam-si (KR)

(21) Appl. No.: 16/353,662

(22) Filed: Mar. 14, 2019

(30) Foreign Application Priority Data
Jun. 21, 2018 (KR) 10-2018-0071499

(51) Int. Cl. H01L 33/50; H01L 33/60; H01L 33/04; H01L 33/56

(52) U.S. Cl. CPC H01L 33/504; H01L 33/60; H01L 33/04; H01L 2933/0091; H01L 2933/0041; H01L 2933/0033; H01L 33/56

(57) ABSTRACT

Provided are a manufacturing method of mass-producing a nano or micro color conversion light emitting diode by a photolithography process, and a nano or micro color conversion light emitting diode manufactured therefrom.

### CROSS-REFERENCE TO RELATED APPLICATIONS

The present application claims priority to Korean Application No. Application No. 10-2018-0071499 entitled “MANUFACTURING METHOD OF COLOR CONVERSION DIODE,” filed on Jun. 21, 2018. The entire contents of the above-listed application are hereby incorporated by reference in their entirety for all purposes.

### TECHNICAL FIELD

The following disclosure relates to a novel manufacturing method of color conversion diode and a novel fine color conversion diode manufactured therefrom.

### BACKGROUND

A light emitting diode (LED) is one of the light emitting display elements which emit light when current is applied thereto. Since the light emitting diode may emit light with high efficiency at low voltage, it has an excellent energy saving effect, and recently, since a brightness problem of the light emitting diode has been greatly improved, the light emitting diode is applied to various devices of a display such as a backlight unit of a liquid crystal display device, an electronic display board, an indicator, and a home appliance.

Light emitting of a display is composed of pixels which are individual light emitting units, and a manufacturing method of the pixel includes mounting (disposing) red, green and blue light emitting diode chips inside a leadframe cup, and electrically connecting the red, green and blue light emitting diode chips by a method such as wiring. In the entire chip and the wiring part, a protective layer is filled into the leadframe cup. In the case of this technique, the size of the pixel is determined by the size of the leadframe, and thus, the size is mostly at least 500 μm or more. There is a disadvantage in that a micro light emitting diode having a pixel size of 100 μm or less is impossible by the conventional leadframe process.

Meanwhile, most of the display device techniques uses three light emitting diode (red, green and blue) chips for implementing one pixel. However, since there is a difference in drive current for each chip due to a difference in an EPI material, it is difficult to configure the same drive circuit.

Accordingly, for solving this problem, a color conversion process based on the same light source (blue or UV LED) is applied to develop a technique of configuring red, green, and blue colors, however, the size of micro color conversion light emitting diode (μ-LED) at a level of 0.1 to 100 μm is still very small, and thus, manufacture with the conventional color conversion process using silicon (a non-photosensitive material) and a fluorescent substance is almost impossible. In addition, in the conventional color conversion process, silicon and a fluorescent substance are combined to form a color conversion cell on the light emitting diode by a dispensing or screen printing method, and in the case of 100 μm or more, the process is effective to some extent, but in the case of fine patterns of 100 μm or less, process realization is almost impossible and many process defects occur, and thus, the conventional color conversion process has many problems in actual commercialization.

Accordingly, it is required in the art to develop a novel manufacturing method which may easily manufacture an ultrafine color conversion light emitting diode having a size of 0.1 to 100 μm all together, as described above.

In addition, in the present invention, even for the unit pixel size of about 0.1 to 100 μm, the height of a color conversion cell may be formed to be 1 to 200 times, and preferably 5 to 200 times the height of each side of the unit pixel by a photolithography process, and thus, a maximum color conversion rate may be secured. That is, the aspect ratio may be 1 to 200 times, and more preferably 5 to 200 times.

### RELATED ART DOCUMENTS

### Patent Documents

(Patent Document 1) U.S. Pat. No. 7,968,894 B2

### SUMMARY

An embodiment of the present invention is directed to providing a novel method capable of mass-producing a color conversion light emitting diode, a micro color conversion light emitting diode obtained therefrom, having a width and length size of 0.1 to 100 μm, and a display device using the same.

That is, an embodiment of the present invention is directed to providing a manufacturing method of a nano- or micrometer-sized ultrafine color conversion light emitting diode and a micro display device manufactured therefrom. In addition, an embodiment of the present invention is directed to providing a manufacturing method of a novel micro color conversion light emitting diode display device on which red, green, and blue color conversion cells are mounted by patterning of a transparent/photosensitive resin including a fluorescent substance in a pixel at a level of 0.1 to 100 μm.

In addition, an embodiment of the present invention is directed to providing a manufacturing method of a plurality of color conversion light emitting diodes by the same process.

In addition, in the present invention, even with the size of the unit pixel of about 0.1 to 100 μm, the height of a color conversion cell may be formed to be 1 to 200 times, and preferably 5 to 200 times the height of each side of the unit pixel by a photolithography process, and thus, a maximum color conversion rate may be secured. That is, the aspect ratio may be 1 to 200 times, and more preferably 5 to 200 times.

Problems to be solved of the present invention are not limited to the above-mentioned objects, and other objects that are not mentioned may be obviously understood by those skilled in the art to which the present invention pertains from the following description.

As a result of conducting studies for solving the above objects, it was found that on an upper portion of a panel on which a blue light emitting diode or ultraviolet (UV) light emitting diode manufactured by a semiconductor process is formed in a plurality of fine patterns, red, green, and blue color conversion cells having an area corresponding to each of the fine patterns are formed on the fine patterns by a photolithography process, thereby providing a method of manufacturing a micro color conversion light emitting diode very simply, reliably, and economically. Thus, the present invention was completed.

That is, in the present invention, by introducing a process of mounting color conversion cells by a photolithography method on an upper portion of the light emitting diode formed in fine patterns, means for mass-producing a color conversion light emitting diode was developed, and also, through this, an ultrafine color conversion light emitting diode which was not manufactured conventionally may be manufactured.

For example, in the color conversion cells, the red cell is mounted by coating a red conversion cell composition including a photosensitive material and quantum dots or a fluorescent substance emitting a red color and/or a light scattering enhancer (e.g., silica) and a solvent and subjecting the coated composition to light irradiation and development by the photolithography process and rinsing, the green conversion cell is mounted by coating a green conversion cell composition including a photosensitive material and quantum dots or a fluorescent substance emitting a green color and/or a light scattering enhancer (e.g., silica) and a solvent and subjecting the coated composition to the photolithography process, and the blue conversion cell is mounted on the same plane continuously.

In the present invention, the red, green, and blue color conversion cells are color conversion cells formed correspondingly on the blue diode or UV diode pattern formed on the panel, by a semiconductor process, and by forming the red, green, and blue color conversion cells by the photolithography process, a fine color conversion light emitting diode which may be mass-produced at the same time, has no defects, and has a width and length size of 0.1 to 100 μm may be produced, and particularly, an excellent color conversion light emitting diode which has a height 1 to 200 times, and preferably 5 to 200 times the width and length size may be mass-produced, which was impossible in the past.

As described above, the reason why the height is larger than the width and length size in the present invention is related to a color conversion rate. The quantum dots or the fluorescence substance for color conversion on an upper portion of the ultrafine pattern should be sufficiently thick, so that a blue or UV light source emitted from the light emitting diode passes through a fluorescent substance layer to transfer sufficient energy for color conversion. The color conversion occurs by the energy transferred to the fluorescent substance, and when the thickness is small, sufficient color conversion does not occur. Accordingly, since the fluorescent substance layer for color conversion should be thick, a pattern having an excellent high aspect ratio of the height 1 to 200 times, preferably 5 to 200 times the width and length size is required.

A manufacturing method of the color conversion cell is as follows:

First, a panel on which a UV LED or blue LED light source formed in a micro pattern form is mounted is prepared. The light source is formed to be divided into three sections on one unit pixel. Subsequently, on the light source which is the panel formed in a plurality of micro patterns, the quantum dots or the fluorescent substance corresponding to one of the red, green, and blue colors (first color) and/or a light scattering enhancer (e.g., silica) and a photosensitive resin, and selectively a solvent when needed are mixed to prepare a composition, the composition is coated by a common coating method, for example, various methods such as spin coating or bar coating, dip coating, flow coating, or the like, and light exposure is performed using a mask in which a portion corresponding to any one section of the light source is perforated. Then, development and rinsing are performed to form the color conversion light emitting diode of a first color, thereby completing a first color conversion cell.

Then, again, a mixture of the quantum dots or the fluorescent substance corresponding to the second color and/or the light scattering enhancer (e.g., silica) and the photosensitive resin, and selectively a solvent when needed is coated in the same manner, light exposure is performed, and development and rinsing are performed to form a diode cell corresponding to the second color. Subsequently, a diode having the third color is also formed in the same manner, thereby manufacturing a display device in which a plurality of unit pixels in which the red, green, and blue diode cells are mounted on the same plane on the upper portion of each section of the light source (on the upper portion of the panel of the unit pixel, the section surface corresponding to three light sources is mounted) are formed in a fine pattern form. The present invention relates to the display device and the manufacturing method thereof.

In the present invention, each of the color conversion light emitting diodes of the fine pattern is cut and arranged, whereby the diode may be used as a display, or a plurality of fine patterns may be continuously arranged to constitute one display.

In the present invention, since position alignment of a photomask used in the photolithography or the like may be performed by exclusively using the technique used in a semiconductor photolithography process and is well known in the art, a detailed description thereon will be omitted.

In addition, the present invention provides a display device which is manufactured by mounting the nano- or micrometer-sized color conversion cells constituting red, green, and blue colors which correspond to the light emitting diode based on the same nano- or micrometer-sized light emitting diode (blue or UV), using a photolithography process, and a manufacturing method thereof.

In the present invention, the light source is separately divided to correspond to the color conversion cells disposed on the light source and emits light, thereby converting various colors by on-off of the green, red, and blue conversion cells.

Accordingly, the present invention provides a display device having the unit pixels manufactured by mounting red, green, and blue cells which are color conversion cells having different color conversion wavelengths from each other to correspond to surfaces forming the three nano- or micrometer-sized light emitting diodes (blue or UV), by the photolithography process, and a manufacturing method thereof.

In addition, the present invention provides a nano- or micrometer-sized micro-display device by mounting the red, green, and blue diodes correspondingly to the size by the photolithography method on a surface of the blue or UV diode, and also a manufacturing method thereof.

Hereinafter, specific means will be summarized as follows.

In the present invention, a color conversion light emitting diode is manufactured by a photolithography process, including: preparing a panel on which a light source layer divided into a plurality of fine patterns is formed, and mounting a color conversion cell formed by the photolithography process on the light source layer of the panel, whereby a mass production method of fine color conversion light emitting diode having a size of 0.1 to 100 μm was completed.

In the present invention, the color conversion cell is formed in three microsections of a red conversion cell, a green conversion cell, and a blue conversion cell, and on the panel on which the color conversion cell is to be formed, the light source is divided into three microsections corresponding to three microsections of the red conversion cell, the green conversion cell, and the blue conversion cell.

In addition, an aspect ratio (height/(length or width) which is a ratio of a height to a width or a length of the color conversion light emitting diode of the present invention is 1 to 200, preferably 5 to 200.

The present invention provides a mass production method of a color conversion light emitting diode, in which the light source is any one selected from the group consisting of a blue LED and an ultraviolet LED, and also when the light source is the blue LED, the light conversion cell is the red light conversion cell and the green light conversion cell formed on the same surface on the upper portion of the light source.

In the present invention, the color conversion cell is mounted by the photolithography process, after coating a material including quantum dots or a fluorescent substance capable of color conversion and/or a light scattering enhancer (e.g., silica) and a photosensitive resin, and a solvent to be added when needed on the panel, thereby completing a mass production method of a color conversion light emitting diode.

In the present invention, the color conversion cell is manufactured by coating a material including each of the quantum dots or a fluorescent substance emitting each color and/or a light scattering enhancer (e.g., silica) and a photosensitive resin, and a solvent when needed on the panel on which the UV or blue LED light source formed, performing light exposure by irradiating UV through a mask having perforated portions corresponding to the microsections of the light source corresponding to a position at which each of the color conversion cells is formed, removing the mask, performing development and rinsing using the solvent, and repeating the process, whereby a color conversion light emitting diode and a mass production method thereof were completed.

In addition, the present invention may further include a baking process between the coating process and the light exposure process, between the development process and the rinsing process, and after the rinsing process.

In the present invention, the quantum dot compound may be any one or two or more selected from the group consisting of ZnS, ZnSe, ZnTe, CdS, CdSe, CdTe, and InP; and the fluorescent substance is not particularly limited as long as the fluorescent substance may emit green, red, and blue colors, and for example, a green fluorescent substance may be any one or two or more selected from the group consisting of β-SiAlON:Eu²⁺ series materials, ZnS:Cu,Al, SrAl₂O₄:Eu, and BAM:Eu,Mn, a red fluorescent substance may be any one or two or more selected from the group consisting of K₂SiF₆:Mn (hereinafter, referred to as “KSF”), CaAlSiN₃:Eu (hereinafter, referred to as “CASN”), Y₂O₂S:Eu, La₂O₂S:Eu, 3.5MgO.0.5MgF₂.GeO₂:Mn, and (La,Mn,Sm)₂O₂S.Ga₂O₃, a blue fluorescent substance may be any one or two or more selected from the group consisting of BAM:Eu, Sr₅(PO₄)₃Cl:Eu, ZnS:Ag, and (Sr,Ca,Ba,Mg)₁₀(PO₄)₆Cl₂:Eu, and a white fluorescent substance is any one or two or more selected from the group consisting of YAG:Ce, nitride and oxy-nitride fluorescent substances.

In the present invention, the light scattering enhancer is mainly composed of particles such as silica, the size may be from 1 nm to 10 μm, and the size of the light scattering enhancer may be selected depending on the size of the fluorescent substance combined together.

In addition, in the present invention, the panel may be selected from the group consisting of silicon, sapphire, a glass plate, and a plastic film/sheet. In addition, the plastic film/sheet may the selected from the group consisting of a polycarbonate-based resin, an acrylic resin, a styrenic resin, a polyester-based resin, a polyamide-based resin, a polynorbornene-based resin, a polysulfone-based resin, and a polyimide-based resin.

In addition, the present invention may be the color conversion light emitting diode including the color conversion cells formed from a material including a quantum dot compound or a fluorescent substance and/or a light scattering enhancer (e.g., silica) and a photosensitive resin, and a solvent to be added when needed, on an upper surface of the light source selected from the group consisting of a blue LED or an ultraviolet LED, wherein the color conversion light emitting diode has a size of 0.1 to 100 μm and an aspect ratio of 1 to 200. In the present invention, the color conversion cell may be formed in three microsections of a red conversion cell, a green conversion cell, and a blue conversion cell, and in the light source also, the color conversion cell may be divided into three microsections corresponding to three microsections of the red conversion cell, the green conversion cell, and the blue conversion cell. In addition, when the light source is the blue LED, the light conversion cell is the red light conversion cell and the green light conversion cell formed on the same surface on the upper portion of the light source, and the light source itself may serve as the blue conversion cell.

In the present invention, the photosensitive resin composition may include a multifunctional group-containing monomer or resin capable of reacting with radicals produced by light to cause photopolymerization, but not limited thereto, and may further include a photoinitiator catalyst, and the photoinitiator may be for example, any one or two or more selected from the group consisting of an aceteophenone derivative, a benzophenone derivative, a triazine derivative, a biimidazole derivative, an acylphosphine oxide derivative, an oxime ester derivative, a hexafluoroantimonate salt, a triarylsulfonium salt, a diaryliodonium salt, and N-hydroxysuccinimide triflate.

In the present invention, the color conversion cell may further include an adhesive binder, and the adhesive binder may be, as a non-limiting example, any one or two or more selected from the group consisting of an epoxy-based resin, a melamine-based resin, a silicon-based resin, a phenolic resin, an acrylic resin, a urethane-based resin, and a urethane-acrylic resin.

In addition, in the present invention, the photosensitive resin composition may further include any one or more components selected from the group consisting of a binder, a photosensitizer, a thermal polymerization inhibitor, a defoaming agent, and a leveling agent, and may be a protective layer further formed on the upper portion of the color conversion cell.

In addition, the present invention may further include a light filter or a light preservation layer in the inside of or on the upper portion of the color conversion cell, and each of the color conversion cells is formed to be separated from each other or formed to be separated by a wall.

The light filter or the light preservation layer further intervenes in the inside of or on the upper portion of the color conversion cell, thereby filtering or amplifying light to further enhance brightness or strength of the light emitting diode. The light filter, the light preservation layer, or the light amplification layer of the present invention is not limited as long as it is used in the art.

Other features and aspects will be apparent from the following detailed description, the drawings, and the claims.

### BRIEF DESCRIPTION OF THE DRAWINGS

FIG. 1A-1D illustrate a conceptual diagram of the present invention.

FIG. 2 illustrates a SEM photograph of a color conversion cell manufactured by a photolithography process of the present invention.

### DETAILED DESCRIPTION OF EMBODIMENTS

The advantages, features and aspects of the present invention will become apparent from the following description of the embodiments with reference to the accompanying drawings, which is set forth hereinafter. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, the present invention will be described using the drawings. In addition, after the drawing is understood, the present invention is further described, or the exemplary embodiments of the present invention will be further described.

In the drawings of the present invention, each name or structure and each constitutional element may be exaggeratedly expressed for convenience. Further, terms used in the present specification have the general meaning understood by those skilled in the art to which the present invention pertains unless otherwise defined, and a description for the known function and configuration unnecessarily obscuring the gist of the present invention will be omitted in the following description and the accompanying drawings.

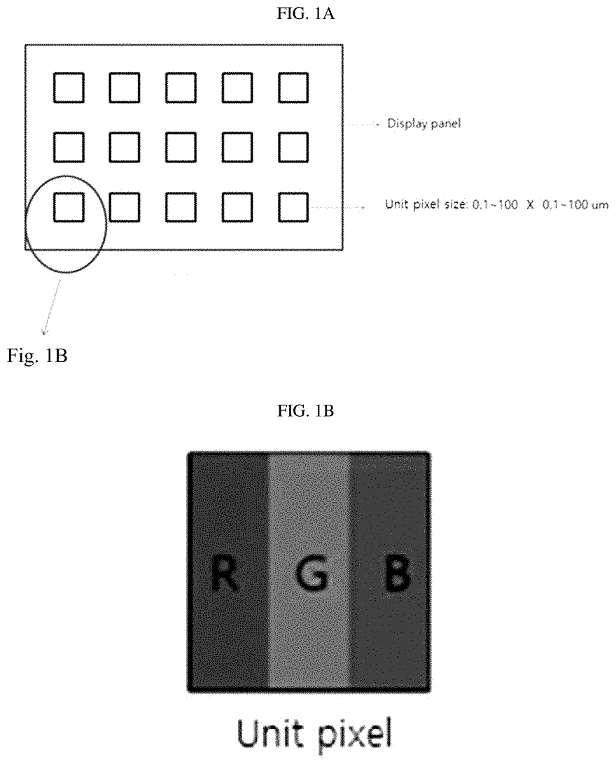

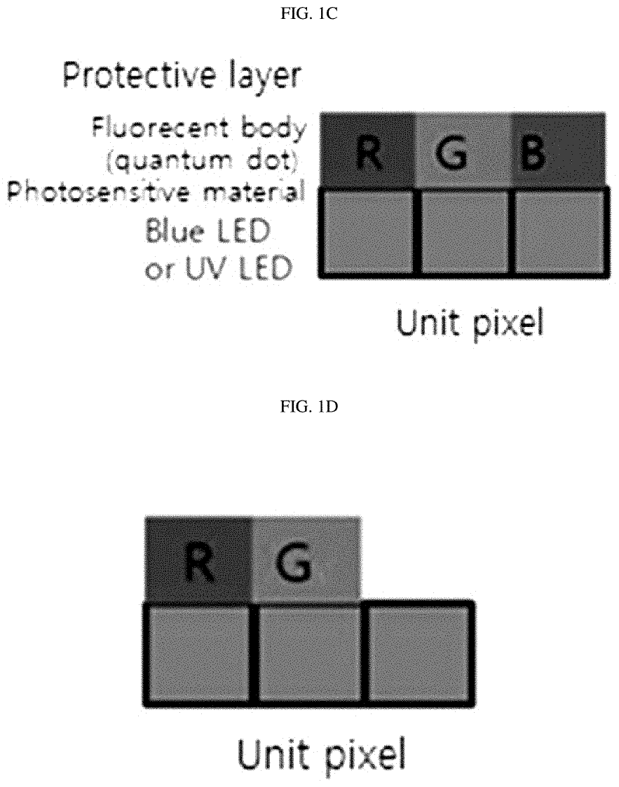

FIG. 1A-1D are a conceptual diagram of the present invention.

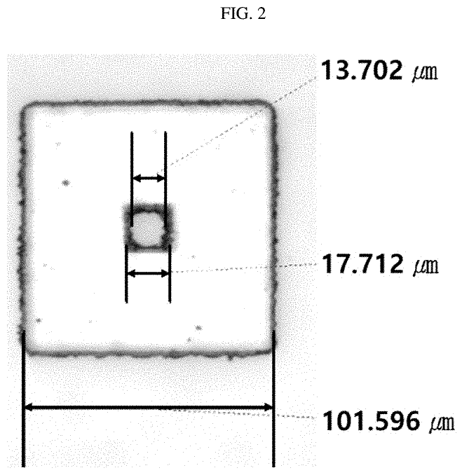

FIG. 2 is a SEM photograph of the actually manufactured color conversion cell of the present invention.

FIG. 1A, illustrates a display panel in which color conversion diodes are mounted in the form of a plurality of fine patterns (unit pixel) on a panel, FIG. 1B illustrates one structure of one unit pixel among fine pattern (unit pixel) forms, viewed from an upper surface, and FIG. 1C and FIG. 1D illustrate one possible example of a laminated structure of a unit pixel which is the one fine pattern.

As easily seen from FIG. 1A, the present invention has a fine pattern corresponding to each of the color conversion diode, which has a very fine width and length size of 0.1 to 100 μm, and possibly a width and length size of even 0.01 μm may be manufactured by the photolithography process.

FIG. 1C shows a structure in which red, green, and blue conversion cells formed by the photolithography process are mounted on the section of each light source when a UV LED or blue LED is used as a light source, and herein three color conversion cells are mounted on one plane. Of course, the color conversion cells may be mounted on the light source of the three sections on a plane other than the same plane. For example, an additional light filter or a light preservation layer may be formed in the inside of or on the upper portion of the color conversion cell, or a protective layer may be interposed therebetween, and thus, various cases may occur.

In addition, FIG. 1D illustrates the case that when a blue LED is used as a light source, a blue color conversion cell is not formed, only red and green color conversion cells are formed on one plane, and the light source may be used as it is without forming the blue conversion cell separately.

The basic concept of the present invention has been described using FIG. 1A-1D as described above, and hereinafter, the exemplary embodiments, the constitution and the effect of the present invention will be described by specific illustration referring to the drawings.

FIG. 2 is a form of the actually manufactured color conversion cell in the micro color conversion diode according to the present invention. As seen from FIG. 2, when the color conversion cell is formed on the light source by the photolithography process of the present invention, the present invention has an effect of significantly improving the brightness of color converted light due to manufacture of a color conversion cell having a much larger height than a width and a length of the color conversion cell by the photolithography process, as well as advantages of mass production and manufacture of fine conversion cells having a size of 0.1 to 100 μm. FIG. 2 is a photograph of the color conversion cell manufactured by dispersing quantum dots of 5 nm in a mixture of a negative photosensitive resin composition and toluene, coating and masking the mixture, irradiating ultraviolet light (180 mJ/cm²) thereon, drying (baking) at 95° C. for 5 minutes, and then rinsing for 10 minutes using isopropyl alcohol. In FIG. 2, the height of the color conversion cell is a thickness of 72 μm.

In addition, in the present invention, the color conversion cell may be manufactured in various shapes such as circle, square, rectangle and rhombus, thereby having an advantage of increasing the possibility of design.

With the size of the unit pixel of the color conversion light emitting diode according to the present invention, the fine color conversion diode having a width and length size of 0.1 to 100 μm may be produced, and particularly the excellent color conversion light emitting diode having a height 1 to 200 times, preferably 5 to 200 times the width and length size, which was impossible in the past may be mass-produced by the photolithography process, thereby securing a maximum color conversion rate. That is, the aspect ratio may be 1 to 200 times, and more preferably 5 to 200 times.

In the present invention, significance of achieving the technology capable of significantly improving the height by the photolithography process is very big. As described above, the reason why a height is larger than a width or length size in the present invention is related to a color conversion rate. The quantum dots or the fluorescence substance for color conversion on an upper portion of the ultrafine pattern should be sufficiently thick, so that a blue or UV light source emitted from the light emitting diode passes through a fluorescent substance layer to transfer sufficient energy for color conversion. The color conversion occurs by the energy transferred to the fluorescent substance, and when the thickness is small, sufficient color conversion does not occur. Accordingly, since the fluorescent substance layer for color conversion should be thick, a pattern having an excellent high aspect ratio of the height 1 to 200 times, preferably 5 to 200 times the width and length size is required. Accordingly, adoption of the photolithography process capable of producing the color conversion light emitting diode of 100 μm or less, having a significantly increased height, has also very important technical significance.

Next, the manufacturing method of the color conversion light emitting diode according to one exemplary embodiment of the present invention will be described.

The present invention relates to a manufacturing method of the color conversion light emitting diode (display) by a photolithography process, including:

preparing a panel on which a light source layer divided into a plurality of fine patterns is formed, and

mounting a color conversion cell formed by the photolithography process on the light source layer of the panel.

In addition, the present invention relates to a manufacturing method of the color conversion light emitting diode (display) by a photolithography process, including:

preparing a panel on which a blue LED or UV LED light source is formed in a plurality of micro patterns, which is divided into three microsections per each micro pattern, and

forming red, green, and blue color conversion cells to correspond to the area of three microsections of each of the fine patterns on the three microsections by the photolithography process.

In addition, the present invention provides a manufacturing method of the color conversion light emitting diode by a photolithography process, including forming the color conversion cell by the photolithography process, and then further forming a protective layer.

In the light emitting diode of the present invention, the color conversion cells may be formed to be separated from each other, or may be formed to be separated by a wall.

In addition, in the present invention, a baking process may be further included between the coating process and the light exposure process, between the development process and the rinsing process, and after the rinsing process.

The baking process is, when there is a thermoreactive group not a photoreactive group among functional groups of the photosensitive resin in the photosensitive resin composition, to cure the composition harder by the process. In this case, usually various functional groups such as a hydroxyl group and an isocyanate group, or amine and an isocyanate group, or an epoxy group are introduced to induce a chemical reaction by heat, that is, a curing reaction to further enhance the strength of the color conversion cell.

In the manufacturing method of the color conversion cell according to one aspect of the present invention, the cell is formed to have an area to correspond to the surface of the UV or blue LED by the photolithography process.

That is, each of the fine patterns firstly formed on the panel has a UV LED or blue LED light source divided into three microsections, and on the surface of each of the microsections, the red, green, or blue color conversion cell having an area corresponding to the surface is formed by the photolithography process, thereby mass-producing the color conversion light emitting diode.

That is, as an example, first, in order to form the red cell, a coating composition for a red conversion cell is prepared by mixing a material including quantum dots or a fluorescent substance emitting a red color and/or a light scattering enhancer (e.g., silica) and a photosensitive resin, and a solvent which is selectively included when needed, the composition is coated (for example, spin coated) on a panel on which a UV or blue LED light source is formed, UV is irradiated through a mask having perforated portions corresponding to microsections of the UV or blue LED light source on which the red cell is to be formed, then the mask is removed, and development and rinsing are performed using the solvent, thereby forming the red conversion cell.

Then, in order to form a green conversion cell, a coating composition for a green conversion cell is prepared by mixing a material including quantum dots or a fluorescent substance emitting a green color and/or a light scattering enhancer (e.g., silica) and a photosensitive resin, and a solvent which is selectively included, the composition is coated (for example, spin coated) on a panel on which a UV or blue LED light source is formed, UV is irradiated through a mask having perforated portions on a position corresponding to microsections of the UV or blue LED light source on which the green conversion cell is to be formed, and development and rinsing are performed, thereby forming the green conversion cell.

In the present invention, when the light scattering enhancer is added, a surprising effect of increasing the brightness by preferably 20% or more is shown, which is further preferred.

Then, finally, a coating composition for a blue conversion cell including a material including quantum dots or a fluorescent substance emitting a blue color and/or a light scattering enhancer (e.g., silica) and a photosensitive resin, and a solvent which is selectively included is prepared, the composition is coated (for example, spin coated) on a panel on which the red conversion cell and the green conversion cell are formed, UV is irradiated through a mask having perforated portions corresponding to microsections of the UV or blue LED light source on which the blue conversion cell is to be formed, and development and rinsing are performed, thereby forming the blue conversion cell.

In the present invention, when the blue LED is used as the light source above, in addition to mounting the red, green, and blue cells on the same plane on the UV LED or blue LED corresponding to the sections, it is not necessary to form the blue cell as the color conversion cell, and thus, only the red and green cells are mounted by the photolithography process on the same plane and the light source itself is used as the blue cell, and in this case, only the red cell and the green cell are mounted on the same plane.

The quantum dot or the fluorescent substance which may be adopted in the present invention are not limited as long as they are used in the art, and for example, the quantum dot compound may be any one or two or more selected from the group consisting of ZnS, ZnSe, ZnTe, CdS, CdSe, CdTe, and InP, but not limited thereto.

In addition, the fluorescent substance is not particularly limited as long as the fluorescent substance may emit green, red, and blue colors, and for example, a green fluorescent substance may be any one or two or more selected from the group consisting of β-SiAlON:Eu²⁺ series materials, ZnS:Cu, Al, SrAl₂O₄:Eu, and BAM:Eu,Mn, a red fluorescent substance may be any one or two or more selected from the group consisting of K₂SiF₆:Mn (hereinafter, referred to as “KSF”), CaAlSiN₃:Eu (hereinafter, referred to as “CASN”), Y₂O₂S:Eu, La₂O₂S:Eu, 3.5MgO.0.5MgF₂.GeO₂:Mn, and (La,Mn,Sm)₂O₂S.Ga₂O₃, a blue fluorescent substance may be any one or two or more selected from the group consisting of BAM:Eu, Sr₅(PO₄)₃Cl:Eu, ZnS:Ag, and (Sr,Ca,Ba,Mg)₁₀(PO₄)₆Cl₂:Eu, and a white fluorescent substance may be any one or two or more selected from the group consisting of YAG:Ce, nitride and oxy-nitride fluorescent substances, but not limited thereto.

The color conversion cell may be characterized by further including the light enhancer.

In addition, in the present invention, the panel may be selected from the group consisting of silicon, sapphire, a glass plate, and a plastic film/sheet, and the panel is not limited in the present invention as long as the panel is used in the art. In addition, the plastic film and sheet may be used for manufacturing a flexible display, and though not particularly limited, for example, any one or two or more selected from the group consisting of a polycarbonate-based resin, an acrylic resin, a styrenic resin, a polyester-based resin, a polyamide-based resin, a polynorbornene-based resin, a polysulfone-based resin, a polyimide-based resin, and the like may be adopted, and a plastic such as polyimide which has low thermal resistance and coefficient of expansion and is also transparent is more preferred.

In the present invention, the photosensitive resin composition is not particularly limited as long as the composition includes a material which is crosslinked or decomposed by ultraviolet ray, X-ray, or the like, and usually it is common and preferred in the present invention to include a multifunctional group-containing monomer or resin which may react with a radical produced by light to cause photopolymerization.

Usually, a mixture of a multifunctional acrylic oligomer or monomer and a monofunctional acrylic monomer may be used, and more preferably, when the composition is prepared only with a monomer without using a solvent, contamination of a display by the compound may be prevented, which is more preferred.

In the present invention, the photosensitive resin composition may further include a photoinitiator catalyst, and the photoinitiator is not limited as long as the photoinitiator is used in the art, and the photoinitiator may be for example, any one or two or more selected from the group consisting of an acetophenone derivative, a benzophenone derivative, a triazine derivative, a biimidazole derivative, an acylphosphine oxide derivative, an oxime ester derivative, a hexafluoroantimonate salt, a triarylsulfonium salt, a diaryliodonium salt, N-hydroxysuccinimide triflate, and the like, but not limited thereto.

The photosensitive resin composition of the present invention may further include a solvent for viscosity or coatability. The solvent is not particularly limited, but may be for example, any one or two or more selected from the group consisting of 2-heptanone, cyclopentanone, cyclohexanone, ethylbenzene, toluene, xylene, phenol, ethyllactate, 1-methoxy-2-propanol, 2-methoxy-1-propanol, 1-methoxy-2-propylacetate, 2-methoxy- 1-propylacetate, propylene carbonate ethyl acetate, butyl acetate, ethylethoxypropionate, methylcellosolve acetate, ethylcellosolve acetate, diethylene glycol methyl acetate, diethylene glycol ethyl acetate, acetone, methylisobutyl ketone, dimethylformamide, N,N-dimethylacetamide, N-methyl-2-pyrrolidine, γ-butyrolactone, diethylether, ethyleneglycol dimethyl ether, diglyme, tetrahydrofuran, methylcellosolve, ethylcellosolve, diethylene glycol methyl ether, diethylene glycol ethyl ether, dipropylene glycol methyl ether, and the like.

In addition, in the present invention, the photosensitive resin composition may further include a binder by necessity, which increases strength in the color conversion cell to be produced, and is preferred for structural stability particularly even when a flexible display is repeatedly bent. Though the binder of the present invention is not particularly limited, the binder may be for example, any one or two or more selected from the group consisting of an epoxy-based resin, a melamine-based resin, a silicon-based resin, a phenolic resin, an acrylic resin, a urethane-based resin, a urethane-acrylic resin, and the like.

In the present invention, the photosensitive composition may be any one as long as the composition has a structure which may be crosslinked or decomposed by light, and may further include a photoinitiator for photoreaction, and since any photosensitive composition may be adoptable as long as it is used in a common photolithography process, description thereof will be omitted.

In addition, in the present invention, the photosensitive resin composition of the present invention may further include any one or more components selected from the group consisting of a binder, a photosensitizer, a thermal polymerization inhibitor, a defoaming agent, and a leveling agent.

In addition, the color conversion light emitting diode of the present invention may be formed by further including a protective layer on the color conversion cell. The protective layer protects the color conversion light emitting diode of the present invention from external impact or a compound or oxygen to prolong a life or allow long-term use. The protective layer may be a protective layer using a UV curable resin, or a layer formed by laminating a separate transparent protective film.

Usually, as the protective film, the film selected from the group consisting of thermoplastic polymer films such as polyolefin, polyvinylacetate, polyvinylalcohol, polyurethane, polyamide, polyester, and polyimide may be used, but is not limited as long as the film has been developed as the protective film of common electronic devices or the protective film for devices for electronics.

In addition, in the present invention, a light filter or a light preservation layer further intervenes in the inside of or on the upper portion of the color conversion cell, thereby filtering or amplifying light to further enhance brightness or strength of the light emitting diode. The light filter, the light preservation layer, or the light amplification layer of the present invention is not limited as long as it is used in the art.

Since in the present invention, a micro light emitting diode (UV light emitting diode or blue light emitting diode) having a semiconductor CMOS circuit and a single color without physical transfer or electrical connection (soldering) or adhesion and metallization process of the light emitting diode is formed and a color conversion process proceeds, the process of the present invention is simple.

Since the present invention has no separate transfer process during a display process, a time to manufacture a display panel may be minimized. For example, in the case of the conventional micro display, it takes a month on average to manufacture a 55″ monitor, whereas in the case of the present invention, the monitor may be manufactured within 12 hours.

The present invention adopts the photolithography process as a process of manufacturing a color conversion diode, unlike the conventional process, whereby a color conversion cell of 100 μm or less may be manufactured, preferably a color conversion cell of 1 μm or less may be formed without difficulty, and thus, a fine color conversion diode having a size of about 0.1 to 100 μm may be easily manufactured.

In addition, in the present invention, even with the size of the unit pixel of 0.1 to 100 μm, the height of a color conversion cell may be formed to be 1 to 200 times, and preferably 5 to 200 times the height of each side of the unit pixel by a photolithography process, and thus, the bright ness may be excellently increased without damage of the brightness. That is, the aspect ratio may be 1 to 200 times, and more preferably 5 to 200 times.

Accordingly, the present invention solves a problem of decreasing the size of a diode which acts as a limitation in a subminiature display or an electronic devices, thereby providing a novel manufacturing method which overcome the limitation on manufacture of a subminiature electronic display device and also promotes improvement of brightness.

In addition, the present invention has an effect of minimizing reduction of efficiency and brightness by an interaction between a color conversion fluorescent substances or active ions even with low driving voltage.

Furthermore, in the present invention, since color conversion is made for each nano- or micrometer-sized color conversion cell, the problems such as increased volume or increased capacity which may occur when the color conversion cells are mixed or laminated for using may be fundamentally solved, and mixing of colors are performed naturally at low cost.

The quantum dots and the fluorescent substance according to the present invention are not limited as long as they may emit red, green and blue colors. For example, a silicate series, a garnet series including YAG, a fluoride series, a sulfide series, a nitride series, or the like may be included, but not limited thereto.

The form of the color conversion light emitting diode corresponding to each of the fine patterns of the present invention may be circular, or polygonal such as square, rectangular, triangular, pentagonal, or hexagonal structure, or other structure.

What is claimed is:

1. A mass production method of a color conversion light emitting diode (display) by the photolithography process, comprising:
preparing a panel on which a light source layer divided into a plurality of fine patterns is formed, and mounting a color conversion cell formed by a photolithography process on the light source layer of the panel, wherein the color conversion light emitting diode has a size of 0.1 to 100 μm.

2. The mass production method of a color conversion light emitting diode of claim 1, wherein the color conversion cell is formed in three microsections of a red conversion cell, a green conversion cell, and a blue conversion cell.

3. The mass production method of a color conversion light emitting diode of claim 1, wherein the light source is divided into three microsections corresponding to the three microsections of the red conversion cell, the green conversion cell, and the blue conversion cell.

4. The mass production method of a color conversion light emitting diode of claim 1, wherein the color conversion cell has an aspect ratio of 1 to 200.

5. The mass production method of a color conversion light emitting diode of claim 1, wherein the red conversion cell, the green conversion cell, and the blue conversion cell are mounted on the same plane.

6. The mass production method of a color conversion light emitting diode of claim 1, wherein the light source is any one selected from the group consisting of a blue LED and an ultraviolet (UV) LED.

7. The mass production method of a color conversion light emitting diode of claim 6, wherein when the light source is the blue LED, a light conversion cell is a red light conversion cell and a green light conversion cell formed on the same surface on an upper portion of the light source.

8. The mass production method of a color conversion light emitting diode of claim 1, wherein the color conversion cell is formed by coating a material including quantum dots or a fluorescent substance and a photosensitive resin on the panel, and using the photolithography process.

9. The mass production method of a color conversion light emitting diode of claim 3, wherein the color conversion cell is formed by coating a material including each of the quantum dots or the fluorescent substance emitting each color and the photosensitive resin on the panel on which the UV or blue LED light source is formed, performing light exposure by irradiating UV through a mask having perforated portions corresponding to microsections of the light source corresponding to a position at which each of the color conversion cells is formed, removing the mask, performing development and rinsing using a solvent, and repeating the process.

10. The mass production method of a color conversion light emitting diode of claim 9, further comprising a baking process between the coating process and the light exposure process, between the development process and the rinsing process, and after the rinsing process.

11. The mass production method of a color conversion light emitting diode of claim 8, wherein the quantum dots are any one or two or more selected from the group consisting of ZnS, ZnSe, ZnTe, CdS, CdSe, CdTe, and InP.

12. The mass production method of a color conversion light emitting diode of claim 8, wherein the fluorescent substance is green, red and blue fluorescent substances, the green fluorescent substance is any one or two or more selected from the group consisting of β-SiAlON:Eu²⁺ series materials, ZnS:Cu,Al, SrAl₂O₄:Eu, and BAM:Eu,Mn, the red fluorescent substance is any one or two or more selected from the group consisting of K₂SiF₆:Mn, CaAlSiN₃:Eu, Y₂O₂S:Eu, La₂O₂S:Eu, 3.5MgO.0.5MgF₂.GeO₂:Mn, and (La,Mn,Sm)₂O₂S.Ga₂O₃, and the blue fluorescent substance is any one or two or more selected from the group consisting of BAM:Eu, Sr₅(PO₄)₃Cl:Eu, ZnS:Ag, and (Sr,Ca,Ba,Mg)₁₀(PO₄)₆Cl₂:Eu.

13. The mass production method of a color conversion light emitting diode of claim 1, wherein the color conversion cell further includes a light enhancer.

14. The mass production method of a color conversion light emitting diode of claim 1, wherein the panel is selected from the group consisting of silicon, sapphire, a glass plate, and a plastic film/sheet.

15. The mass production method of a color conversion light emitting diode of claim 14, wherein the plastic film/sheet is selected from the group consisting of a polycarbonate-based resin, an acrylic resin, a styrenic resin, a polyester-based resin, a polyamide-based resin, a polynorbornene-based resin, a polysulfone-based resin, and a polyimide-based resin.

16. A color conversion light emitting diode, comprising a color conversion cell formed from a composition including any one or more components selected from the group consisting of quantum dots and a fluorescent substance and a photosensitive resin on an upper portion of a light source selected from the group consisting of a blue LED and an ultraviolet LED, and having a width and length size of 0.1 to 100 μm, respectively, wherein the color conversion cell has an aspect ratio of 1 to 200.

17. The color conversion light emitting diode of claim 16, wherein the color conversion cell is formed in three microsections of a red conversion cell, a green conversion cell, and a blue conversion cell.

18. The color conversion light emitting diode of claim 16, wherein the light source is divided into three microsections corresponding to the three microsections of the red conversion cell, the green conversion cell, and the blue conversion cell.

19. The color conversion light emitting diode of claim 18, wherein the red conversion cell, the green conversion cell, and the blue conversion cell are formed on the same plane.

20. The color conversion light emitting diode of claim 16, wherein when the light source is a blue LED, a light conversion cell is a red light conversion cell and a green light conversion cell formed on the same surface on an upper portion of the light source.

21. The color conversion light emitting diode of claim 16, wherein the quantum dots are any one or two or more selected from the group consisting of ZnS, ZnSe, ZnTe, CdS, CdSe, CdTe, and InP.

22. The color conversion light emitting diode of claim 16, wherein the fluorescent substance is green, red and blue fluorescent substances, the green fluorescent substance is any one or two or more selected from the group consisting of β-SiAlON:Eu²⁺ series materials, ZnS:Cu,Al, SrAl₂O₄:Eu, and BAM:Eu,Mn, the red fluorescent substance is any one or two or more selected from the group consisting of K₂SiF₆:Mn, CaAlSiN₃:Eu, Y₂O₂S:Eu, La₂O₂S:Eu, 3.5MgO.0.5MgF₂.GeO₂:Mn, and (La,Mn,Sm)₂O₂S.Ga₂O₃, and the blue fluorescent substance is any one or two or more selected from the group consisting of BAM:Eu, Sr₅(PO₄)₃Cl:Eu, ZnS:Ag, and (Sr,Ca,Ba,Mg)₁₀(PO₄)₆Cl₂:Eu.

23. The color conversion light emitting diode of claim 16, wherein the color conversion light emitting diode is formed on any one panel selected from the group consisting of silicon, sapphire, a glass plate, and a plastic film/sheet.

24. The color conversion light emitting diode of claim 23, wherein the plastic film/sheet is selected from the group consisting of a polycarbonate-based resin, an acrylic resin, a styrenic resin, a polyester-based resin, a polyamide-based resin, a polynorbornene-based resin, a polysulfone-based resin, and a polyimide-based resin.

25. The color conversion light emitting diode of claim 16, wherein the photosensitive resin composition includes a multifunctional group-containing monomer or resin which reacts with a radical produced by light to cause photopolymerization.

26. The color conversion light emitting diode of claim 25, wherein the photosensitive resin composition further includes a photoinitiator catalyst.

27. The color conversion light emitting diode of claim 26, wherein the photoinitiator catalyst is any one or two or more selected from the group consisting of an aceteophenone derivative, a benzophenone derivative, a triazine derivative, a biimidazole derivative, an acylphosphine oxide derivative, an oxime ester derivative, a hexafluoroantimonate salt, a triarylsulfonium salt, a diaryliodonium salt, and N-hydroxysuccinimide triflate.

28. The color conversion light emitting diode of claim 16, wherein the color conversion cell further includes an adhesive binder.

29. The color conversion light emitting diode of claim 28, wherein the adhesive binder is any one or two or more selected from the group consisting of an epoxy-based resin, a melamine-based resin, a silicon-based resin, a phenolic resin, an acrylic resin, a urethane-based resin, and a urethane-acrylic resin.

30. The color conversion light emitting diode of claim 16, wherein the photosensitive resin composition further includes any one or more components selected from the group consisting of a binder, a photosensitizer, a thermal polymerization inhibitor, a defoaming agent, and a leveling agent.

31. The color conversion light emitting diode of claim 16, further comprising a protective layer on an upper portion of the color conversion cell.

32. The color conversion light emitting diode of claim 16, further comprising a light filter or a light preservation layer in the inside of or on the upper portion of the color conversion cell.

33. The color conversion light emitting diode of claim 16, wherein each of the color conversion cells is formed to be separated from each other or formed to be separated by a wall.

34. The color conversion light emitting diode of claim 16, wherein each of the color conversion cells further includes a light scattering enhancer.

35. The color conversion light emitting diode of claim 28, wherein each of the color conversion cells further includes a light scattering enhancer.
